(19) United States
(12) Patent Application Publication
(10) Pub. No.: US 2006/0051894 A1
(43) Pub. Date: Mar. 9, 2006

(54) Method for bonding flip chip on leadframe

(75) Inventors: Chien Liu, Kaohsiung City (TW); Meng Jen Wang, Pingtung City (TW); Sheng Tai Tsai, Kaohsiung City (TW)

Correspondence Address: LOWE HAUPTMAN GILMAN AND BERNER, LLP, 1700 DIAGONAL ROAD, SUITE 300 /310, ALEXANDRIA, VA, 22314, US

(73) Assignee: ADVANCED SEMICONDUCTOR ENGINEERING, INC., Kaohsiung City (TW)

(21) Appl. No.: 11/217,573

(22) Filed: Sep. 2, 2005

(30) Foreign Application Priority Data
Sep. 6, 2004 (TW) 093126914

(51) Int. Cl. H01L 21/48; H01L 21/50

(52) U.S. Cl. 438/108; 438/123; 438/124

(57) ABSTRACT

A method for bonding flip chip on leadframe is disclosed. A leadframe including a plurality of leads is provided. The leadframe is oxidized to form an oxidation layer from the upper surface of the leads. Each lead has a flip-chip bonding portion covered by the oxidation layer. A flip chip is flip-chip bonded to the leadframe via bumps. A flux is applied on the bumps of the flip chip, and part of the oxidation layer on the flip-chip portions is removed. Therefore the bumps can be reflowed and connect the flip-chip portions of the leads.

This application claims the priority benefit of Taiwan Patent Application Serial Number 093126914 filed Sep. 6, 2004, the full disclosure of which is incorporated herein by reference.

### BACKGROUND OF THE INVENTION

1. Field of the Invention

The invention relates to a technology of a flip-chip on a leadframe, and more particularly, to a method for bonding a flip chip on a leadframe.

2. Description of the Related Art

The conventional flip-chip package is to bond a flip chip onto a substrate (circuit board). However, for cost-down purpose, a low-cost packaging method is to directly flip-chip bond a flip chip to a leadframe having a plurality of leads. However, as a result of good wetability, the bumps on the flip chip are prone to spread to any position on the leads of the leadframe in a reflow step and therefore collapse. This makes the flip chip extremely close to the leads of the leadframe and thus reduces the resistance of the package to stress. The bumps are therefore likely to be broken. Reference is now made to FIG. 1 where there is shown a typical flip chip 10 in the prior art. The flip chip 10 has an active surface 11 and a back surface 12. A plurality of bumps 13, e.g. tin-lead bumps or other reflowable bumps is disposed on the active surface 11. As the flip chip 10 is flip-chip bonded to a leadframe 20, the bumps 13 will be reflowed so as to be soldered to the plurality of leads 21 of the leadframe 20. However, as a result of good wetability of the bumps 13, the bumps 13 are likely to spread to any position on the leads 21 and therefore the gaps between the flip chip 10 and leads 21 cannot be retained. This causes the problems of bump collapse and reduction of resistance to stress.

In order to solve these problems, the Taiwan Patent Publication Number 498517, entitled “LEADFRAME WITH A FUNCTION OF CONTROLLING THE COLLAPSE QUANTITY AND FLIP CHIP SEMICONDUCTOR PACKAGE HAVING THE LEADFRAME”, disclosed that a leadframe for flip-chip bonding has a plurality of leads and a die pad. The height of the die pad is larger than the thicknesses of the leads so as to uphold the active surface of the flip chip and control the degree of collapse of the bumps on the flip chip. However, the wetting spread areas on the leads defined by the bumps can still not be defined this manner. The bumps will have neck shapes after experiencing a reflow process and are likely to be broken. Besides, the die pad also limits the shapes of the leads of the leadframe.

The Taiwan Patent Publication Number 540123, entitle “FLIP-CHIP SEMICONDUCTOR PACKAGE WITH LEAD FRAME AS CHIP CARRIER”, disclosed a flip-chip semiconductor package. The package has a flip chip, a leadframe and an encapsulant. The flip chip is bonded to the leadframe and encapsulated by the encapsulant, wherein each of the leads of the leadframe is provided with a dam member in an appropriate position (upper surface). A soldering area is formed on between the end of a lead and the dam member pertaining to the lead. Each of the tin-lead bumps of the flip chip is bonded to the soldering area of each of the leads so as to prevent the bumps from being improperly wetting spread in the reflow step. However, the dam members are made of plastic film or printed resin, and they are extra elements mounted on the leadframe. They can only define the soldering areas for soldering the bumps on the upper surfaces of the leads, but can not prevent the side surfaces of the leads from improperly wetting spread by bumps in the reflow step. Accordingly, the bumps are likely to spread to the side surfaces of the leads. Besides, the mounting of the dam members to the leadframe will increase manufacturing cost and cause a problem of misalignment.

### SUMMARY OF THE INVENTION

The object of the present invention is to provide a method for flip-chip bonding to leadframe. The method is to provide an oxidized leadframe having a plurality of leads, which are oxidized to form an oxidation layer thereon. Each of the leads has a flip-chip bonding portion covered by the oxidation layer. As a flip chip is flip-chip bonded to the leadframe a flux is applied to the bumps of the flip chip, whereby the oxidation layer on the flip-chip bonding portions of the leads can be removed. This causes the bumps to be reflowed and connected to the flip-chip bonding portions of the leads, and the bumps to be limited by the un-removed oxidation layer on the flip-chip bonding portions. The bumps are unable to spread to other upper surfaces and side surfaces of the leads. The method can limit the soldering area on the leadframe to which the bumps are bonded with lower cost.

According to the method for flip-chip bonding to leadframe of the present invention, the method provides an oxidized leadframe defining a plurality of leads, wherein the upper surfaces of the leads are oxidized to form an oxidation layer, and each lead defines a flip-chip bonding portion covered by the oxidation layer. A flip chip is provided with a plurality of bumps, e.g. tin-lead bumps or reflowable bumps. A flux is formed on the bumps. Only the part of the oxidation layer on the flip-chip bonding portions is removed by the flux as the flip chip is flip-chip bonded to the leadframe so as to facilitate the bumps to be reflowed and connected to the flip-chip bonding portions of the leads. The spread of the bumps is restrained by the un-removed oxidation layer surrounding the flip-chip bonding portions to prevent the collapse of the bumps so as to retain the gaps between the flip chip and leads.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a cross-sectional view showing a flip chip bonded to a leadframe in the prior art.

FIG. 2 is a cross-sectional view of a leadframe according to a method for bonding flip chip on leadframe of the present invention.

FIG. 3 is a cross-sectional view showing that a flip chip is about to be bonded to a leadframe according to a method for bonding flip chip on leadframe of the present invention.

FIG. 4 is a cross-sectional view of a flip chip bonded to a leadframe according to a method for bonding flip chip on leadframe of the present invention.

FIG. 5 is a cross-sectional view showing that a flip-chip is bonded to a leadframe and encapsulated by an encapsulant according to a method for bonding flip chip on leadframe of the present invention.

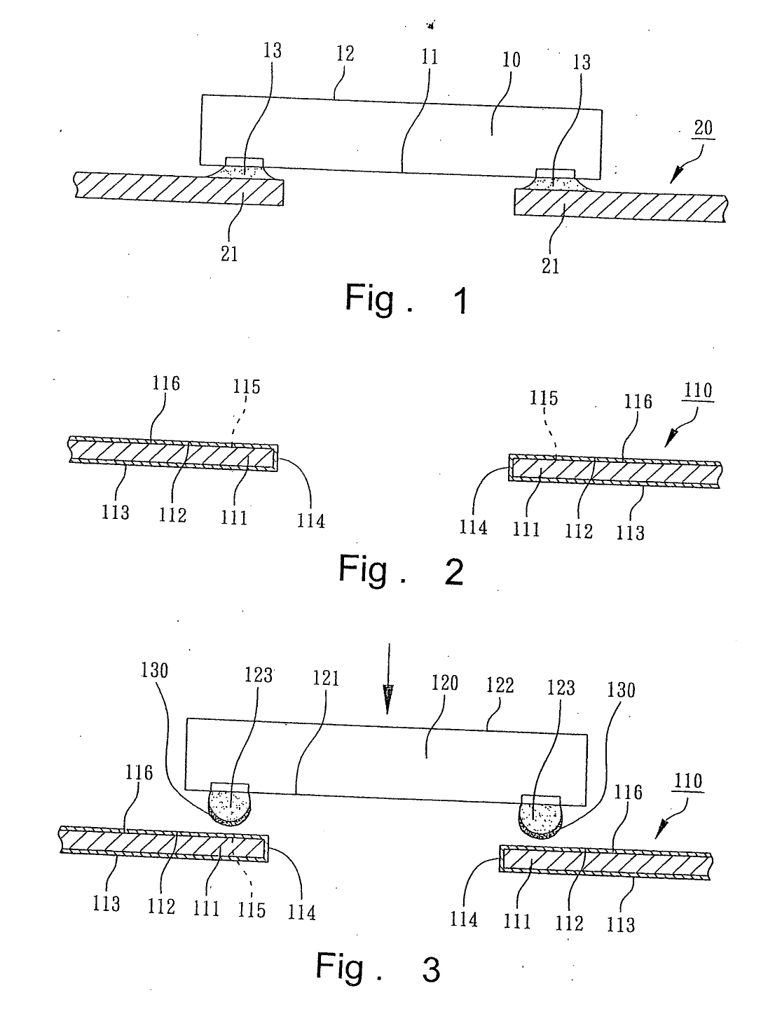

### DETAILED DESCRIPTION OF THE PREFERRED EMBODIMENT

According to the method for flip-chip bonding on leadframe, referring to FIG. 2, firstly, an oxidized leadframe 110 for flip-chip bonding is provided and the leadframe 110 is processed by oxidation to present black or brown. The leadframe 110 includes a plurality of leads 111, each of which defines an upper surface 112, a lower surface 113 and a plurality of side surfaces 114 between the upper surface 112 and lower surface 113. An oxidation layer 116 is formed on the upper surfaces 112 of the leads 111, and the oxidation layer 116 has the composition of copper (Cu) contained in the leadframe 110. The oxidation layer 116 can be, e.g. a black layer or a brown layer by different processes, preferably, the oxidation layer 116 is also formed on the lower surfaces 113 and side surfaces 114 of the leads 111. In this embodiment, the leadframe 110 is made of copper. The oxidation layer 116 can be formed by immersing the leadframe 110 in a sodium chlorite solution or putting the leadframe 110 in an oven with an oxidizing atmosphere so as to form a cuprous oxide or a copper oxide as the oxidization layer 116. The cuprous oxide and copper oxide are low-cost protective films for protecting the leadframe 110 and can substitute for the known films, solder masks, resin dams and other extra dam members. Each of leads 111 has a flip-chip bonding portion 115 covered by the oxidation layer 116. In this embodiment, the flip-chip bonding portions 115 are defined on the inner sides of the leads 111 and hid under the oxidation layer 116 of the upper surface 112. There is no need to define the flip-chip bonding portions 115 by specific shapes or extra elements. Furthermore, the leadframe 110 has no need to be provided with a die pad, which is helpful to design and dispose the leads 110 thereof.

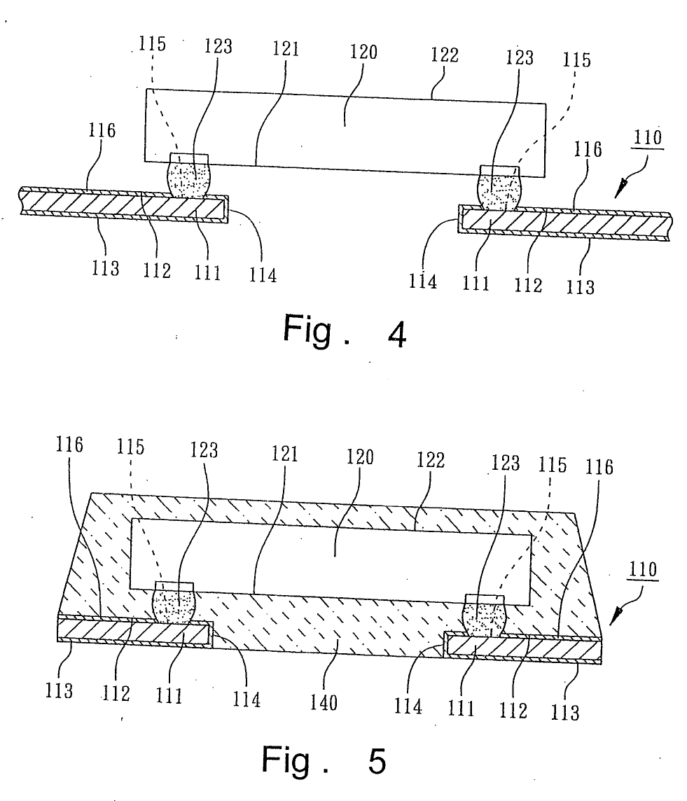

Reference is now made to FIG. 3 where there is show a flip chip 120. The flip chip 120 has an active surface 121, a back surface 122 and a plurality of bumps 123, e.g. tin-lead bumps or other reflowable bumps disposed on the active surface 121. Furthermore, before flip-chip bonding the flip chip 120 a flux 130 is formed on the bumps 123 in printing or application. In this embodiment, the flux 130 can be the flux sold under the trademark Sparkle Flux, part no. 385 manufactured by SENJU METAL INDUSTRY, which is excellent in removing the oxidation layer formed on a metal. Reference is now made to FIGS. 3 and 4, as the flip chip 120 is flip-chip bonded to the leadframe 110, the flux 130 on the bumps 123 will first contact the oxidation layer 116 on the upper surface 112 and rapidly remove the oxidation layer 116 on the flip-chip bonding portions 115. The bumps 123 are bonded to the flip-chip bonding portions 115 of the leads 111 and the spread of the bumps can be restrained by the un-removed part of the oxidation layer 116 surrounding the flip-chip bonding portion 115, which is not removed by the flux 130. The collapse of the bumps 123 can be avoided and therefore the gaps between the flip chip 120 and leads 111 are retained.

Since the oxidation layer 116 has the performance of restraining the spread of the bumps 123 and therefore the leadframe 110 can be protected, and the bumps 123 do not spread to and contaminate the upper surfaces 112, side surfaces 114 and lower surfaces 113 of the leads 111 other than the flip-chip bonding portions 115, the soldering areas on which the bumps 123 are soldered to the leadframe 110 can be controlled in a low-cost way. Therefore, the bumps 123 have enough rooms between the flip chip 120 and leads 111 for having good soldering to ensure good resistance to stress.

Referring to FIG. 5, after flip-chip bonding flip chip 120 to the leadframe 110, an encapsulant 140 can be formed by molding or dispensing. The encapsulant 140 encapsulates the bumps 123 and flip chip 120. In this embodiment, the encapsulant 140 encapsulates the upper surfaces 112 and side surfaces 114 of the leads 111, and exposes the lower surfaces 113 of the leads 111 so as to form a leadless flip-chip package. In addition, the oxidation layer 116 formed on the leadframe 110 by oxidation can also enhance the bonding of between the leadframe 110 and encapsulant 140.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A method for flip-chip bonding on leadframe, comprising the steps of:
providing an oxidized leadframe defining a plurality of leads, each of the leads defining an upper surface having an oxidation layer, each of the leads defining a flip-chip bonding portion covered by the oxidation layer;
providing a flip chip with a plurality of bumps;
forming a flux on the bumps; and
flip-chip bonding the flip chip to the leadframe so as to bond correspondingly the bumps to the flip-chip bonding portions of the leads, wherein the flux is used to remove the oxidation layer on the flip-chip bonding portion so as to facilitate the bumps to be reflowed and connected to the flip-chip bonding portions of the leads.

2. The method as claimed in claim 1, wherein the bumps are tin-lead bumps.

3. The method as claimed in claim 1. the method further comprising the step of:
forming an encapsulant to encapsulate the bumps.

4. The method as claimed in claim 3, wherein the encapsulant exposes the lower surfaces of the leads.

5. The method as claimed in claim 1, wherein the oxidation layer is further formed on the lower surfaces and side surfaces of the leads.

6. The method as claimed in claim 1, wherein the oxidation layer is a black layer.

7. The method as claimed in claim 1, wherein the oxidation layer is a brown layer.
